(19) United States
(12) Patent Application Publication
(10) Pub. No.: US 2007/0293049 A1
(43) Pub. Date: Dec. 20, 2007

(54) Slurry for CMP of Cu film, polishing method and method for manufacturing semiconductor device

(76) Inventors: Gaku Minamihaba, Yokohama-shi (JP); Dai Fukushima, Kamakura-shi (JP); Hiroyuki Yano, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/812,185

(22) Filed: Jun. 15, 2007

(30) Foreign Application Priority Data
Jun. 20, 2006 (JP) 2006-170224

(51) Int. Cl. H01L 21/461; H01L 21/302; C03C 15/00

(52) U.S. Cl. 438/692; 438/693; 216/89; 51/307

(57) ABSTRACT

A slurry for CMP of Cu film is provided, which includes water, peroxosulfuric acid or a salt thereof, basic amino acid, a complexing agent which forms a water-insoluble metal complex, a surfactant, and colloidal silica having a primary diameter ranging from 5 to 50 nm. The basic amino acid is included at a content of 0.05 to 0.5 wt %.

### CROSS-REFERENCE TO RELATED APPLICATIONS

This application is based upon and claims the benefit of priority from prior Japanese Patent Application No. 2006-170224, filed Jun. 20, 2006, the entire contents of which are incorporated herein by reference.

### BACKGROUND OF THE INVENTION

1. Field of the Invention

This invention relates to a slurry for CMP of Cu film, to a polishing method, and to a method of manufacturing a semiconductor device.

2. Description of the Related Art

The Cu damascene wiring to be mounted on a high-performance LSI is generally formed by CMP. In this CMP, a Cu film is removed at first in a first polishing and then redundant portions of metal and insulating film are removed in a second polishing. In order to shorten the processing time, the first polishing should desirably be performed as high rate as possible. Accordingly, the Cu film is increasingly demanded to be capable of meeting the requirement of high polishing rate. In this case, the barrier metal to be employed as an underlying layer is not only required to be incapable of being substantially polished but also required to be capable of minimizing the dishing or corrosion of Cu film. In order to realize these requirements, a slurry containing peroxosulfate as an oxidizing agent is employed in the aforementioned first polishing.

However, since it is expected in future that the thickness of barrier metal becomes increasingly thinner and the polishing quantity in the second polishing is increasingly reduced, it would become more difficult to sufficiently minimize the dishing or corrosion of Cu film even if a conventional slurry containing peroxosulfate is employed. Namely, although it is now desired to polish the Cu film at a high rate while making it possible to obviate the problems such as the dishing of the Cu film, the corrosion of the Cu film, and the residual Cu without necessitating the existence of a thick barrier metal, no one has succeeded as yet to find out a slurry which makes it possible to perform the polishing while obviating these problems.

Incidentally, there has been proposed the employment of a slurry containing basic amino acid for polishing a Cu-based film which is formed on a tantalum-based metal film acting as a barrier metal. In this case, due to the interaction between the basic amino acid and the tantalum-based metal film, the polishing rate of the tantalum-based metal film can be reduced, thus securing excellent performance as a stopper for the CMP of the Cu film. Therefore, according to this slurry, the employment of a tantalum-based metal film is essential and the corrosion of the Cu film is not taken into account.

### BRIEF SUMMARY OF THE INVENTION

A slurry for CMP of Cu film according to one aspect of the present invention comprises water; peroxosulfuric acid or a salt thereof; 0.05 to 0.5 wt % of basic amino acid; a complexing agent which forms a water-insoluble metal complex; a surfactant; and colloidal silica having a primary diameter ranging from 5 to 50 nm.

A polishing method according to another aspect of the present invention comprises contacting a semiconductor substrate having a Cu film with a polishing pad attached to a turntable; and applying dropwise a slurry for CMP of Cu film to the polishing pad to polish the Cu film, the slurry comprising water; peroxosulfuric acid or a salt thereof; 0.05 to 0.5 wt % of basic amino acid; a complexing agent which forms a water-insoluble metal complex; a surfactant; and colloidal silica having a primary diameter ranging from 5 to 50 nm.

A method for manufacturing a semiconductor device according to another aspect of the present invention comprises forming an insulating film above a semiconductor substrate; forming a recess in the insulating film; forming a metal film including a barrier film and a Cu film successively on an inner surface of the recess and above the insulating film; and removing the metal film deposited above the insulating film by CMP using a slurry for CMP of Cu film while leaving the metal film inside the recess, the slurry comprising water; peroxosulfuric acid or a salt thereof; 0.05 to 0.5 wt % of basic amino acid; a complexing agent which forms a water-insoluble metal complex; a surfactant; and colloidal silica having a primary diameter ranging from 5 to 50 nm.

A method for manufacturing a semiconductor device according to another aspect of the present invention comprises forming an insulating film above a semiconductor substrate; depositing a metal above the insulating film to form a CMP sacrificial film; forming a recess penetrating into the insulating film and the CMP sacrificial film; forming a barrier film and a Cu film successively on an inner surface of the recess and on the CMP sacrificial film to obtain a metal film including the CMP sacrificial film, the barrier film and the Cu film; and removing the metal film deposited above the insulating film by CMP using a slurry for CMP of Cu film to expose the insulating film, the slurry comprising water.; peroxosulfuric acid or a salt thereof; 0.05 to 0.5 wt % of basic amino acid; a complexing agent which forms a water-insoluble metal complex; a surfactant; and colloidal silica having a primary diameter ranging from 5 to 50 nm.

### BRIEF DESCRIPTION OF THE SEVERAL VIEWS OF THE DRAWING

FIG. 1 is a cross-sectional view illustrating one step in the method of manufacturing a semiconductor device according to one embodiment of the present invention;

FIG. 2 is a cross-sectional view illustrating a step following the step shown in FIG. 1;

FIG. 3 is a perspective view illustrating a state of CMP;

FIG. 4 is a cross-sectional view illustrating a step following the step shown in FIG. 2;

FIG. 5 is a cross-sectional view illustrating one step in the method of manufacturing a semiconductor device according to another embodiment of the present invention; and

FIG. 6 is a cross-sectional view illustrating a step following the step shown in FIG. 5.

### DETAILED DESCRIPTION OF THE INVENTION

Next, embodiments of the present invention will be explained as follows.

The slurry for CMP of Cu film according to one embodiment of the present invention contains peroxosulfuric acid or a salt thereof. In this slurry, peroxosulfuric acid or a salt thereof acts as an oxidizing agent. As the examples of the salt, they include ammonium persulfate and potassium persulfate. As compared with other oxidizing agent such as hydrogen peroxide, ozone and potassium periodate, the aforementioned peroxosulfuric acid or a salt thereof is far more effective in suppressing the dishing or corrosion of Cu film.

The content of peroxosulfuric acid or a salt thereof to be employed as an oxidizing agent should preferably be confined to 0.05 to 5% based on a total weight of the slurry for CMP. As long as the content of this oxidizing agent is 0.05 wt % or more, it is possible to polish the Cu film at a polishing rate of 500 nm/min or more. On the other hand, as long as the content of this oxidizing agent is limited to 5 wt % or less, it is possible to suppress the corrosion or dishing of the Cu film to an acceptable range. More preferably, the content of this oxidizing agent should be confined to 0.08 to 3% based on a total weight of the slurry.

In order to inhibit the dishing or corrosion from being generated to an unacceptable extent on the Cu film due to the oxidation of the surface of the Cu film by this oxidizing agent, a protective film-forming agent is included in the slurry for CMP of Cu film according to one embodiment of the present invention. This protective film-forming agent consists of two kinds of complexing agent. One of them forms a water-soluble complex of Cu (this kind of complexing agent will be hereinafter referred to as a water-soluble complexing agent), and the other forms a water-insoluble complex of Cu (this kind of complexing agent will be hereinafter referred to as a water-insoluble complexing agent). By the term “water-soluble”, it means that a wet etching rate is 3 nm/min or more under the condition where the complex co-exists with an oxidizing agent, thus enabling the water-soluble complexing agent to take a role of a polish-accelerating agent. On the other hand, by the term “water-insoluble”, it means that the complex is substantially incapable of being dissolved in water, so that when a wet etching rate is less than 3 nm/min under the condition where the complex co-exists with an oxidizing agent, a less-soluble state in water may be included in this definition.

A basic amino acid may be employed as at least part of the water-soluble complexing agent in the slurry for CMP of Cu film according to one embodiment of the present invention. This basic amino acid can be referred to as a first water-soluble complexing agent, examples thereof including histidine, arginine, lysine and derivatives thereof. This basic amino acid may be employed singly or in combination of two or more. Especially, because of the inclusion of nitrogen-containing heterocycle, histidine is more preferable for use. When histidine is contacted with the surface of Cu film, the nitrogen atom constituting the nitrogen-containing heterocycle is enabled to coordinate with Cu. Since the rest of the ring structure is hydrophobic, the hydrophobic rings are enabled to physically adsorb with each other to form a protective film, thereby suppressing the generation of the corrosion of Cu film.

In order to suppress the dishing or corrosion of Cu film while securing the stability of polishing, the content of the basic amino acid should preferably be confined to the range of 0.05 to 0.5% based on a total weight of the slurry for CMP. If the content of the basic amino acid is less than 0.05 wt %, it would be impossible to suppress the dishing or corrosion of Cu film. On the other hand, if the content of the basic amino acid exceeds 0.5 wt %, the polishing rate of Cu film may deteriorate and, at the same time, defects may be generated in the Cu film. Specifically, it may become impossible to suppress the generation of defects such as the dishing, corrosion or scratching of the Cu film. More preferably, the content of the basic amino acid should be confined to the range of 0.1 to 0.3% based on a total weight of the slurry for CMP.

In addition to the aforementioned basic amino acid, another compound may be incorporated in the slurry as a second water-soluble complexing agent. For example, it is possible to employ organic acids, basic salts and neutral amino acids. As the organic acids, it is possible to employ, for example, formic acid, succinic acid, lactic acid, acetic acid, tartaric acid, fumaric acid, glycolic acid, phthalic acid, maleic acid, oxalic acid, citric acid, malic acid, malonic acid and glutamic acid. As the basic salts, it is possible to employ, for example, ammonia, ethylene diamine, tetramethyl ammonium hydroxide (TMAH), etc. As the neutral amino acids, it is possible to employ glycine, alanine, etc. These compounds may be employed singly or in combination of two or more.

Due to the inclusion of the second water-soluble complexing agent, it is now possible to further enhance the effects of suppressing the dishing or corrosion of Cu film. The effects of the second water-soluble complexing agent can be secured as long as the content thereof confined to the range of 0.01 to 0.5% based on a total weight of the slurry for CMP.

As the water-insoluble complexing agent which forms a water-insoluble or hardly soluble complex together with Cu, it is possible to employ heterocyclic compounds consisting of a six-membered heterocyclic compound or a five-membered heterocyclic compound, both containing at least one nitrogen atom. More specifically, it is possible to employ quinaldinic acid, quinolinic acid, benzotriazole (BTA), benzoimidazole, 7-hydroxy-5-methyl-1,3,4-triazaindolizine, nicotinic acid or picolinic acid. When these compounds are contacted with the surface of Cu film, the nitrogen atom constituting the nitrogen-containing heterocycle is enabled to coordinate with Cu. Since the rest of the ring structure is hydrophobic, the hydrophobic rings are enabled to physically adsorb with each other to form a protective film, thereby suppressing the generation of the corrosion of Cu film. Additionally, since these compounds are capable of forming an oxidation-resisting protective film on the surface of Cu film, the acid resistance of the Cu film can be enhanced. As a result, the generation of the dishing of Cu film can be prominently minimized.

Among the anionic surfactants, some of them are capable of acting as a water-insoluble complexing agent. Among such surfactants, alkyl benzene sulfonate is preferable, examples thereof including potassium dodecyl benzene sulfonate and ammonium dodecyl benzene sulfonate.

The content of the water-insoluble complexing agent should be confined to the range of 0.0005 to 2.0% based on a total weight of the slurry for CMP. As long as the content of the water-insoluble complexing agent is confined within this range, the generation of Cu dishing can be suppressed while making it possible to secure a sufficiently large Cu polishing rate. More preferably, the content of the water-insoluble complexing agent should be confined to the range of 0.0075 to 1.5% based on a total weight of the slurry for CMP.

These water-insoluble complexing agents may be employed singly or in combination of two or more.

As the surfactant to be included in the slurry for CMP of Cu film according to one embodiment of the present invention, it is possible to use an anionic surfactant or a cationic surfactant. Examples of the anionic surfactant include, for example, aliphatic soap, sulfate ester, phosphate ester, carboxylate, sulfonate, potassium dodecyl benzene sulfonate, ammonium dodecyl benzene sulfonate, potassium polycarboxylate, ammonium polycarboxylate, etc. Examples of the cationic surfactant include, for example, aliphatic amine salt, aliphatic ammonium salt, quaternary ammonium salt, simple amine salts containing salt-formable primary, secondary or tertiary amine, modified salts of these compounds, onium compounds such as phosphonium salt and sulfonium salt, cyclic nitrogen compounds such as pyridinium salt, quinolinium salt and imidazolinium salt, and heterocyclic compounds, etc. More specifically, it is possible to employ alkyl amine acetate, cetyl trimethyl ammonium chloride, lauryl trimethyl ammonium chloride, cetyl pyridinium bromochloride, dodecyl pyridinium chloride, and alkyl naphthalene pyridinium chloride.

Further, it is also possible to employ a nonionic surfactant. For example, it is possible to employ fluorine-based nonionic surfactant, polyoxyethylene, PVP (polyvinyl pyrrolidone), acetylene glycol, ethylene oxide adduct thereof, acetylene alcohol, a silicone-based surfactant, polyvinyl alcohol, cyclodextrin, polyvinyl methylether, hydroxyethyl cellulose, etc. In order to secure stable dispersibility, the HLB value of the nonionic surfactant should preferably be 6 or more.

The aforementioned surfactants may be employed singly or in combination of two or more. Because of being hardly susceptible to the influence of electrolyte, it is more preferable to employ polyvinyl pyrrolidone (PVP), acetylene glycol, ethylene oxide adduct thereof, or acetylene alcohol.

The content of these surfactants should be confined to the range of 0.001 to 0.5% based on a total weight of the slurry for CMP. If the content of these surfactants falls out of this range, it may become difficult to sufficiently suppress the generation of the Cu dishing. More preferably, the content of these surfactants should be confined to the range of 0.05 to 0.3% based on a total weight of the slurry for CMP.

The slurry for CMP of Cu film according to one embodiment of the present invention contains, as an abrasive grain, colloidal silica having an average primary particle diameter ranging from 5 to 50 nm. The colloidal silica is employed because there is a little possibility of forming bulky particles (aggregates of secondary particles) that may cause scratches. Meanwhile, fumed silica tends to create bulky particles in addition to prominent non-uniformity in primary particle diameter thereof, thus making it difficult to control the particle diameter of abrasive grain. Alumina is also liable to create bulky particles. Even if it is assumed possible to control the average primary particle diameter of fumed silica and alumina, it is impossible to control the generation of the dishing and scratching on the surface in the polishing process thereof.

The primary particle diameter of the abrasive grain can be determined by a transmission electronic microscope (TEM). First of all, a largest length of particle (dₘ) and a length of particle orthogonally intersecting an intermediate point of said largest length (dₚ) are measured and then an average value of these two lengths ((dₘ+dₚ)/2) is defined as the primary particle diameter. This primary particle diameter is calculated for 100 pieces of particles and then an average value thereof is calculated to define the average primary particle diameter. If the average primary particle diameter of colloidal silica is less than 5 nm, it would become impossible to uniformly polish various patterns due to the generation of non-uniformity in polishing force. Additionally, if the average primary particle diameter of colloidal silica is less than 5 nm, the dispersion stability of silica deteriorates, thus making it impossible to use the colloidal silica. On the other hand, if the average primary particle diameter of colloidal silica exceeds 50 nm, it may become difficult to control the surface roughness Ra of the surface being polished to not more than 3 nm and, at the same time, scratching or dishing would be increased in size. If the Ra of the surface being polished is limited to not larger than 3 nm, it would be acceptable and this Ra can be confirmed by atomic force microscopy (AFM). The average primary particle diameter of colloidal silica should preferably be confined to the range of 15 to 25 nm.

As examples of the colloidal silica whose primary particle diameter is confined to the range of 5 to 50 nm, they include colloidal silica having a primary particle diameter of 5 nm or more and a degree of association of 5 or less. By the term “a degree of association”, it means a value that can be obtained by dividing the diameter of secondary particle formed of a coagulation of primary particles by the diameter of primary particle (diameter of secondary particle/diameter of primary particle). When a degree of association is determined as being one, it means that it is consisted of only primary particle that is monodispersed. The diameter of secondary particle can be measured by dynamic light scattering method, laser diffraction method or electron microscopic method. If the degree of association is higher than 5, the scratching or erosion of the polishing surface may be produced on polishing using a slurry containing, as an abrasive grain, colloidal silica having such a high degree of association.

A first colloidal silica having a primary particle diameter ranging from 5 to 20 nm may be combined with a second colloidal silica having a primary particle diameter ranging from 20 to 50 nm to form a mixture which can be employed as colloidal silica having a primary particle diameter ranging from 5 to 50 nm. In this case, the weight ratio of the first colloidal silica based on a total weight of the first colloidal silica and the second colloidal silica should preferably be confined to the range of 0.6 to 0.9. If this weight ratio of the first colloidal silica is less than 0.6, the characteristics of CMP may become those to be derived from colloidal silica which is singly consisted of the second colloidal silica. As a result, the Ra of polishing surface may exceed 3 nm, resulting in coarse finishing. Additionally, it may become difficult to suppress the dishing to 20 nm or less. On the other hand, if this weight ratio of the first colloidal silica exceeds 0.9, the characteristics of CMP may become those to be derived from colloidal silica which consists solely of the first colloidal silica.

The content of colloidal silica should preferably be confined to the range of 0.05 to 10%, more preferably the range of 0.1 to 5% based on a total weight of the slurry for CMP. As long as the content of colloidal silica is 0.05 wt % or more, it is possible to secure a sufficient polishing force. On the other hand, if the content of colloidal silica is 10 wt % or less, it is possible to limit the generation of the scratching and dishing of Cu film to an acceptable range.

In addition to the aforementioned colloidal silica, an organic particle may be further incorporated in the slurry. As examples of the organic particle, they include, for example, polymethyl methacrylate (PMMA), polystyrene, etc. These organic particles may be formed integral with the aforementioned colloidal silica, thus creating a composite-type particle.

The mechanism of polishing wherein the slurry according to one embodiment of the present invention is employed will be explained in detail as follows. Generally, the polishing of a Cu film is performed in such a manner that the surface of the Cu film is oxidized by an oxidizing agent and then the resultant oxide layer is shaved away by a abrasive grain. Therefore, the employment of an oxidizing agent has been considered as being essential in the slurry for CMP of Cu film. Accordingly, peroxosulfuric acid or a salt thereof has been conventionally incorporated as an oxidizing agent in the slurry.

However, when such a conventional slurry that contains peroxosulfate is used in the polishing of the Cu film, a very thin layer consisting of the residue of Cu may remain on the barrier metal. When the quantity of shaving in the second polishing to be performed subsequent to the removal of the Cu film is decreased down to 50 nm or less, the Cu film or the barrier metal may not be completely removed, thus giving rise to the generation of short (short-circuit) of wiring. Although it is required that the redundant Cu on the barrier metal should be completely removed, it may become very difficult to achieve this if the quantity of shaving is not sufficient enough.

For example, in the case of the slurry where a neutral amino acid is contained therein in addition to peroxosulfate, the barrier metal is required to have a certain degree of film thickness in order to suppress the generation of dishing or corrosion of Cu film. If the barrier metal is formed of a thin film having a thickness of 5 nm or less, it would be impossible to suppress the dishing or corrosion of Cu film. In the case of an MnSiO adhesion layer also where a barrier metal does not substantially exist, the dishing or corrosion of Cu film is generated exceeding an acceptable range.

This MnSiO adhesion layer may be formed according to the following procedure for instance. First of all, a wiring trench is formed in an interlayer insulating film formed of SiO₂ and then a film formed of an alloy of Cu and Mn is deposited all over the surface. This alloy film acts as a seed layer on the occasion of depositing a Cu layer by electrolytic plating. Then, this alloy film is subjected to heat treatment, thereby enabling the Mn in the alloy film to diffuse over the surface of the interlayer insulating film and to react with the elements in the interlayer insulating film. As a result, a stable oxide layer comprising MnSiO as a major component and having a film thickness of 5 nm or less is formed.

Further, by the alloy film as a seed layer, a Cu layer is formed by electrolytic plating. In accordance with the conventional method, CMP is performed to remove redundant portion of the Cu layer, thus forming a Cu wiring in a trench. In this case, the thickness of the MnSiO layer existing between this Cu layer and the interlayer insulating film is as small as 5 nm or less. Therefore, it has been considered difficult to suppress the generation of the dishing or corrosion of the Cu layer.

It has been found out by the present inventors that the aforementioned problem can be overcome by the incorporation of basic amino acid as at least part of a water-soluble protective film-forming agent. Namely, when the slurry according to one embodiment of the present invention is applied to the Cu film, the Cu is oxidized at first by peroxosulfuric acid. Then, a water-insoluble Cu complex and a water-soluble Cu complex are generated, thus quickly forming a protective film on the surface of the Cu film. The protective film to be created in one embodiment of the present invention is high in density for the following reasons. Namely, since the slurry according to one embodiment of the present invention contains as a component thereof a basic amino acid, a weak cation is included in the protective film. Since an anion also exists in the protective film, an adsorption force acts between the weak cation and the anion having redundant ligands, thereby enhancing the density of the protective film. As a result, the generation of the corrosion or dishing of Cu film is assumably suppressed.

Since basic amino acid is not included in the conventional slurries, the protective film to be formed on the surface of Cu film is mainly constituted by anion. Because of this, it is assumed that the adsorption among the water-insoluble Cu complexes is mainly effected through physical adsorption. When a plurality of anions having redundant ligands exists in this protective film, repulsive force is acted among these anions, thus badly affecting the denseness of the protective film. Due to this phenomenon, the conventional slurries are accompanied with the problems of the dishing or corrosion of Cu film. On the other hand, in the case of the slurry containing basic amino acid, the corrosion current density thereof is further increased as compared with the slurry where neutral amino acid is included therein. As a result, not only Cu but also barrier metal such as Ta and Ti is easily oxidized, thus creating an oxide film on the surface of the barrier metal. As already explained above, since a protective film composed of a water-insoluble complex is formed on the surface of Cu film, the surfaces of Cu film and the barrier metal can be both protected by the protective film. Accordingly, the generation of potential difference between the Cu film and the barrier metal can be obviated, thus leading to the suppression of the dishing or corrosion of Cu film.

Moreover, since a water-insoluble complexing agent as well as a surfactant is included in the slurry according to one embodiment of the present invention, it is possible to expect the following effects due to these components. Due to the incorporation of the water-insoluble complexing agent, it is possible to realize a high-polishing rate in spite of the very small Cu-wet etching rate of as small as 3 nm/min or less. Further, due to the incorporation of the surfactant, the water-insoluble complex forming a hydrophobic film can be hydrophilized to such an extent that the water-insoluble complex can be prevented from being dissolved, it is possible to realize a stable polishing. In this manner, the surface of the Cu film is oxidized and protected by the protective film, and this protective film is mechanically removed using colloidal silica employed as an abrasive grain. Especially, since the colloidal silica included in the slurry according to one embodiment of the present invention is confined, with respect to the primary particle diameter thereof, to the range of 5 to 50 nm, it is possible to suppress the generation of dishing of Cu film and to realize a stable polishing to a semiconductor substrate having a various pattern or a trench of various depths.

Even if the barrier metal does not exist substantially, it is possible to suppress the generation of the dishing or corrosion of Cu film using the slurry according to one embodiment of the present invention. The reasons for this may be attributed to the effects of the slurry to enhance the denseness of the protective film as described above.

Further, since the slurry according to one embodiment of the present invention is effective in enhancing the denseness of the protective film composed of a water-insoluble complex and a water-soluble complex, the slurry of the embodiment of the present invention can be effectively applied to the polishing of any kinds of metal other than Cu as long as the metal is capable of forming an organic complex and can be oxidized by peroxosulfuric acid. For example, the Ti film which may be disposed as a barrier metal underlying the Cu film can be removed en bloc by CMP using the slurry according to one embodiment of the present invention. Further, in a case where a metallic hard mask is provided as a CMP sacrificial film below the barrier metal, this metallic hard mask can be removed en bloc by CMP together with the Cu film and the barrier metal.

Meanwhile, the slurry for CMP of Cu film according to one embodiment of the present invention is relatively limited in the polishing rate thereof against metals such as Ta, V, Nb, Rb and compounds thereof. More specifically, the polishing rate of Ta is not more than 5 nm/min or so. Accordingly, when a Ta film having a film thickness of 5 nm or more is provided as a barrier metal below the Cu film, the Cu film can be exclusively removed by CMP while leaving behind this Ta film.

The aforementioned components are mixed with water to obtain the slurry for CMP of Cu film according to one embodiment of the present invention. As the water, it is possible to employ ion-exchange water, pure water, etc. and there is not any particular limitation with regard to the kind of water.

With respect to the pH of the slurry according to one embodiment of the present invention, there is not any particular limitation and hence the pH can be adjusted depending on any particular application aimed at. In order to make it possible to polish a Cu film at a high polishing rate while suppressing the generation of the corrosion or dishing of Cu film and securing the stability of polishing rate, the slurry according to one embodiment of the present invention should preferably be alkalized. Namely, the pH of the slurry should preferably be confined to the range of 8 to 11. For example, the slurry can be alkalized through the addition of a pH adjustor such as potassium hydroxide.

Since the slurry for CMP of Cu film according to one embodiment of the present invention contains peroxosulfuric acid or a salt thereof and a predetermined quantity of basic amino acid in addition to a water-insoluble complexing agent and a surfactant, it is possible to polish a Cu film while suppressing the generation of the residue, dishing and corrosion of Cu film even if the quantity to be shaved away is relatively small. Moreover, since the abrasive grain to be included in the slurry for CMP according to one embodiment of the present invention is formed of colloidal silica having a predetermined primary particle diameter, it is possible to secure also a sufficient polishing rate of Cu film. Since the defectives on the surface of damascene wiring to be formed in this manner can be reduced, it is possible to obtain a semiconductor device of high reliability.

### Embodiment 1

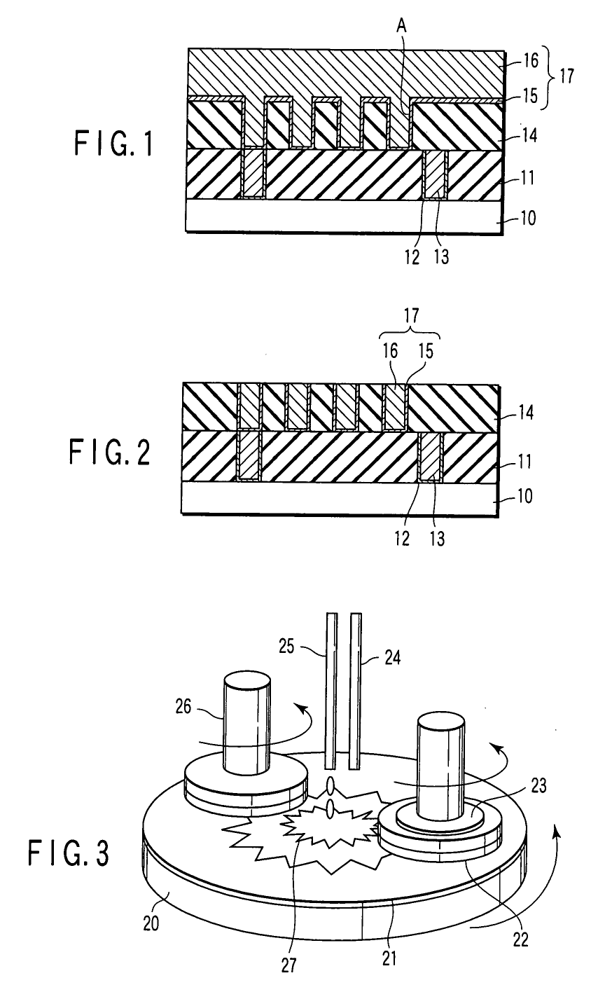

Embodiment 1 will be explained with reference to FIGS. 1 and 2.

First of all, as shown in FIG. 1, an insulating film 11 formed of SiO₂ was deposited on a semiconductor substrate 10 having semiconductor elements (not shown) formed therein and then a plug 13 was formed in the insulating film 11 with a barrier metal 12 being interposed therebetween. The barrier metal 12 was formed by TiN, and the plug 13 was formed by W. Then, a low dielectric constant insulating film 14 was deposited all over the resultant surface.

The low dielectric constant insulating film 14 can be formed by at least one insulating material selected, for example, from the group consisting of SiC, SiCH, SiCN, SiOC and SiOCH. In this embodiment, the low dielectric constant insulating film 14 was formed by SiOC.

Then, a wiring trench “A” having a width of 60 nm was formed as a recess in the low dielectric constant insulating film 14. Thereafter, a Ti film having a thickness of 2 nm and functioning as a barrier metal 15 and a Cu film 16 having a thickness of 800 nm were deposited all over the surface according to the ordinary method. A metal film 17 was constituted by the barrier metal 15 and the Cu film 16.

Thereafter, the Cu film 16 and the barrier metal 15, both constituting the metal film 17 were removed by CMP, thereby filling the wiring trench “A” with the Cu film 16 and the barrier metal 15 and exposing the surface of the low dielectric constant insulating film 14 as shown in FIG. 2. In order to make the low dielectric constant insulating film 14 resistive to the CMP in this case, the relative dielectric constant of the low dielectric constant insulating film 14 should preferably be 2.5 or more. As long as the relative dielectric constant of the low dielectric constant insulating film 14 is limited to 3 or less, there is little possibility of excessively increasing the dielectric constant of the insulating film. This low dielectric constant insulating film 14 may be employed as a capping insulating film and an insulating film which is further lower in dielectric constant may be disposed underneath the low dielectric constant insulating film 14.

The CMP of the Cu film 17 was performed as follows. Namely, as shown in FIG. 3, first of all, while a turntable 20 having a polishing pad 21 attached thereon was continued to rotate at a speed of 100 rpm, a top ring 23 holding a semiconductor substrate 22 was contacted with the polishing pad 21 at a polishing load of 200 gf/cm². The rotational speed of the top ring 23 was set to 105 rpm and a slurry 27 was fed from a slurry feed nozzle 25 to the polishing pad 21 at a flow rate of 200 cc/min. Incidentally, FIG. 3 also shows a water feed nozzle 24 and a dresser 26.

Incidentally, the polishing load of the top ring 23 may be selected from the range of 10 to 1,000 gf/cm², more preferably 30 to 500 gf/cm². Further, the rotational speed of the turntable 20 and the top ring 23 may be selected from the range of 10 to 400 rpm, preferably the range of 30 to 150 rpm. The flow rate of slurry 27 to be fed from the slurry feed nozzle 25 may be selected from the range of 10 to 1,000 cc/min, preferably the range of 50 to 400 cc/min.

Various kinds of slurry as explained below were employed and IC1000 (Rodel Co., Ltd.) was employed as the polishing pad 21. An over-polishing for a period of about 45 seconds was performed on the barrier metal 15 subsequent to the removing step of Cu film 16.

In the preparation of the slurry for polishing the Cu film, the components formulated as follows were at first mixed with pure water to obtain a stock solution. The contents of these components described therein were all based on a total weight of the slurry.

Oxidizing agent: 1.5 wt % of ammonium persulfate Water-insoluble complexing agent: 0.25 wt % of quinaldinic acid

Surfactant: 0.1 wt % of acetylene diole-based nonion (HLB value 18) and 0.06 wt % of ammonium dodecylbenzene sulfonate

Colloidal silica: 0.5 wt % of colloidal silica having a primary particle diameter of 20 nm (association degree: 2)

The stock solution prepared as described above was employed as it was, thus formulating the slurry of sample No. 1. Further, as shown in the following Table 1, various kinds of amino acid was incorporated in the stock solution to obtain the slurries of Nos. 2-11. Potassium hydroxide was added as a pH adjustor to these slurries so as to adjust the pH thereof to 9, ultimately.

TABLE 1

| | | Content |
|---|---|---|
| No. | Amino acid | (wt %) |
| 1 | None | — |
| 2 | Alanine | 0.2 |
| 3 | Lysine | 0.2 |
| 4 | Arginine | 0.2 |
| 5 | Histidine | 0.03 |
| 6 | | 0.05 |
| 7 | | 0.1 |
| 8 | | 0.2 |
| 9 | | 0.3 |
| 10 | | 0.5 |
| 11 | | 0.7 |

The Ti-polishing rate of the slurries prepared in this manner was determined according to the content of colloidal silica. The solid film of Ti was polished to investigate the Ti-polishing rate of these slurries on the basis of sheet resistance. As a result, the Ti-polishing rate of these slurries was all 5 nm/min or more. By performing over-polishing of about 45 seconds, the surface of the low dielectric constant insulating film 14 was exposed.

Using slurry samples shown in above Table 1, the CMP of the Cu film 16 was performed under the same conditions as described above to investigate the Cu-polishing rate. In the determination of this polishing rate, a solid film of Cu having a film thickness of 2000 nm was polished for 60 seconds and, based on the measurements of the sheet resistance, the polishing rate thereof was calculated, wherein the polishing rate was evaluated according to the following criterions. When the polishing rate was found 500 nm/min or more, it was assumed as being acceptable.

◯: 650 nm/min or more

Δ: 500 nm/min to less than 650 nm/min

×: less than 500 nm/min

Further, the dishing and corrosion of the Cu film were investigated.

In the investigation of the dishing, the step portion was determined by an atomic force microscope (AFM) and evaluated according to the following criterions. When the dishing was less than 30 nm, it was assumed as being acceptable.

◯: less than 20 nm

Δ: 20 nm to less than 30 nm

×: 30 nm or more

The corrosion of the Cu film was measured by a defective-evaluating apparatus (KLA; Tenchol Co., Ltd.) and evaluated based on the number of these defectives per cm² and according to the following criterions. If the number of defectives was less than 20 in a sample, the sample was assumed as being acceptable.

◯: less than 5

Δ: 5 to less than 20

×: 20 or more

The results obtained from each of these slurries are summarized in the following Table 2.

TABLE 2

| | Polishing rate | Corrosion | Dishing |
|---|---|---|---|
| No. | (nm/min) | (number) | (nm) |
| 1 | ◯ | X | X |
| 2 | ◯ | X | X |
| 3 | ◯ | ◯ | ◯ |
| 4 | ◯ | ◯ | ◯ |
| 5 | ◯ | X | X |
| 6 | ◯ | Δ | Δ |
| 7 | ◯ | ◯ | ◯ |
| 8 | ◯ | ◯ | ◯ |
| 9 | ◯ | ◯ | ◯ |
| 10 | ◯ | Δ | Δ |
| 11 | ◯ | X | X |

As shown in above Table 2, the slurry of No. 1 containing no amino acid was found unacceptable with respect to the corrosion and dishing of Cu film. The results obtained from the slurry of No. 2 indicate that the corrosion and dishing of Cu film would be deteriorated if alanine which is a neutral amino acid is included in a slurry.

Even if basic amino acid is contained in a slurry, when the content thereof is too small (the slurry of No. 5) or too large (the slurry of No. 11), it is impossible to sufficiently suppress the generation of the corrosion and dishing of Cu film. In the cases of slurries Nos. 3, 4 and 6-10 where the content of basic amino acid was confined within the range of 0.05 to 0.5 wt %, all of the results were found falling within the acceptable range. Especially, in the cases of slurries Nos. 3, 4 and 7-9 where the content of basic amino acid was confined within the range of 0.1 to 0.3 wt %, it was found possible to prominently improve the corrosion and dishing of Cu film.

Then, other kinds of water-soluble complexing agent were added respectively to the slurry of No. 6, thus preparing the slurries of Nos. 12-15.

TABLE 3

| | Water-soluble | Content |
|---|---|---|
| No. | complexing agent | (wt %) |
| 12 | Formic acid | 0.05 |
| 13 | Ammonia | 0.05 |
| 14 | Alanine | 0.2 |
| 15 | | 0.05 |

Using slurry samples shown in above Table 3, the CMP of Cu film was performed under the same conditions as described above to investigate the Cu film-polishing rate. Further, the corrosion and dishing of Cu film were investigated. These results thus obtained were evaluated according to the same criterions as described above, the results thereof being summarized in the following Table 4.

TABLE 4

| | Polishing rate | Corrosion | Dishing |
|---|---|---|---|
| No. | (nm/min) | (number) | (nm) |
| 12 | ◯ | ◯ | ◯ |
| 13 | ◯ | ◯ | ◯ |
| 14 | ◯ | ◯ | ◯ |
| 15 | ◯ | ◯ | ◯ |

As shown in above Table 4, it will be recognized that when these other kinds of water-soluble complexing agent are incorporated in the slurry in addition to basic amino acid, it is possible to improve the corrosion and dishing of Cu film.

Then, the slurries of Nos. 16-19 were prepared so as to have the same composition as that of No. 8 except that the oxidizing agent was changed to those as shown in the following Table 5. Further, the slurry of No. 20 was prepared so as to have the same composition as that of No. 8 except that the oxidizing agent was not incorporated therein at all.

TABLE 5

| No. | Oxidizing agent | Content (wt %) |
|---|---|---|
| 16 | Peroxosulfuric acid | 0.06 |
| 17 | Potassium peroxosulfate | 4 |
| 18 | Hydrogen peroxide | 0.1 |
| 19 | Periodate | 0.1 |

Using slurry samples shown in above Table 5, the CMP of Cu film was performed under the same conditions as described above to investigate the Cu film-polishing rate. Further, the corrosion and dishing of Cu film were investigated. These results thus obtained were evaluated according to the same criterions as described above, the results thereof being summarized in the following Table 6.

TABLE 6

| | Polishing rate | Corrosion | Dishing |
|---|---|---|---|
| No. | (nm/min) | (number) | (nm) |
| 16 | Δ | ◯ | ◯ |
| 17 | ◯ | Δ | Δ |
| 18 | ◯ | X | X |
| 19 | ◯ | X | X |
| 20 | X | X | X |

As shown in above Table 6, in the cases of slurries Nos. 16 and 17 where peroxosulfuric acid or peroxosulfate was included as an oxidizing agent in the slurries, all of the results were found falling within the acceptable range. As seen from the results of Nos. 18 and 19, oxidizing agents other than peroxosulfuric acid or peroxosulfate were included respectively in the slurry, it was impossible to improve the corrosion and dishing of Cu film. As seen from the results of the slurry No. 20, when an oxidizing agent was not included in the slurry, all of the results were found unacceptable.

Then, the slurries of Nos. 21-24 were prepared so as to have the same composition as that of No. 8 except that the water-insoluble complexing agent was changed to those as shown in the following Table 7. Further, the slurry of No. 25 was prepared so as to have the same composition as that of No. 8 except that the water-insoluble complexing agent was not incorporated therein at all.

TABLE 7

| | Water-insoluble | Content |
|---|---|---|
| No. | complexing agent | (wt %) |
| 21 | Quinolinic acid | 0.25 |
| 22 | Benzotriazole | 0.001 |
| 23 | Nicotinic acid | 1.8 |
| 24 | Potassium dodecylbenzene | 0.25 |
| | sulfonate | |

Using slurry samples shown in above Table 7, the CMP of Cu film was performed under the same conditions as described above to investigate the Cu film-polishing rate. Further, the corrosion and dishing of Cu film were investigated. These results thus obtained were evaluated according to the same criterions as described above, the results thereof being summarized in the following Table 8.

TABLE 8

| | Polishing rate | Corrosion | Dishing |
|---|---|---|---|
| No. | (nm/min) | (number) | (nm) |
| 21 | ◯ | ◯ | ◯ |
| 22 | ◯ | Δ | ◯ |
| 23 | ◯ | Δ | ◯ |
| 24 | Δ | Δ | Δ |
| 25 | Δ | Δ | Δ |

As long as a water-insoluble complexing agent is incorporated in the slurry irrespective of the kinds thereof as shown in above Table 8, all of the results were found falling within the acceptable range as shown in the slurries Nos. 21-24. Especially, when a water-insoluble complexing agent having a nitrogen-containing hetero ring is included in the slurry, the acid-resistance of Cu film can be enhanced, thereby making it possible to remarkably minimize the dishing of Cu film. As shown in the slurry of No. 25, even if a water-insoluble complexing agent is not separately incorporated in the slurry, when a surfactant is enabled to act also as a water-insoluble complexing agent, the results to be obtained would become acceptable.

Then, the slurries of Nos. 26-29 were prepared so as to have the same composition as that of No. 8 except that the surfactant was changed to those as shown in the following Table 9. Further, the slurry of No. 30 was prepared so as to have the same composition as that of No. 8 except that the surfactant was not incorporated therein at all.

TABLE 9

| | | Content |
|---|---|---|
| No. | Surfactant | (wt %) |
| 26 | Polyvinyl alcohol | 0.002 |
| 27 | Cyclodextrin | 0.05 |
| 28 | Silicone ethylene | 0.3 |
| | oxide adduct | |
| 29 | Silicone ethylene | 0.4 |
| | oxide adduct | |

Using slurry samples shown in above Table 9, the CMP of Cu film was performed under the same conditions as described above to investigate the Cu film-polishing rate. Further, the corrosion and dishing of Cu film were investigated. These results thus obtained were evaluated according to the same criterions as described above, the results thereof being summarized in the following Table 10.

TABLE 10

| | Polishing rate | Corrosion | Dishing |
|---|---|---|---|
| No. | (nm/min) | (number) | (nm) |
| 26 | ◯ | Δ | ◯ |
| 27 | ◯ | ◯ | ◯ |
| 28 | ◯ | ◯ | ◯ |
| 29 | Δ | ◯ | ◯ |
| 30 | Δ | X | X |

As long as a surfactant is incorporated in the slurry irrespective of the kinds thereof as shown in above Table 10, all of the results were found falling within the acceptable range as shown in the slurries Nos. 26-29. As shown in the slurry of No. 30, when a surfactant is not incorporated in the slurry, the corrosion and dishing of Cu film would become unacceptable.

Then, the slurries of Nos. 31-40 were prepared so as to have the same composition as that of No. 8 except that the abrasive grain was changed to those as shown in the following Table 11.

TABLE 11

| | | Av. primary particle |
|---|---|---|
| No. | Abrasive grains | diameter (nm) |
| 31 | Colloidal silica | 3 |
| 32 | Colloidal silica | 5 |
| 33 | Colloidal silica | 15 |
| 34 | Colloidal silica | 20 |
| 35 | Colloidal silica | 25 |
| 36 | Colloidal silica | 50 |
| 37 | Colloidal silica | 60 |
| 38 | Fumed silica | 20 |
| 39 | Colloidal alumina | 20 |
| 40 | Fumed alumina | 20 |

Using slurry samples shown in above Table 11, the CMP of Cu film was performed under the same conditions as described above to investigate the Cu film-polishing rate. Further, the corrosion and dishing of Cu film were investigated. These results thus obtained were evaluated according to the same criterions as described above, the results thereof being summarized in the following Table 12.

Incidentally, although the slurry No. 34 is the same in composition as that of slurry No. 8, it is shown in Tables 11 and 12 for the purpose of comparison.

TABLE 12

| | Polishing rate | Corrosion | Dishing |
|---|---|---|---|
| No. | (nm/min) | (number) | (nm) |
| 31 | X | Δ | Δ |
| 32 | Δ | ◯ | ◯ |
| 33 | ◯ | ◯ | ◯ |
| 34 | ◯ | ◯ | ◯ |
| 35 | ◯ | ◯ | ◯ |
| 36 | ◯ | ◯ | Δ |
| 37 | ◯ | ◯ | X |
| 38 | ◯ | ◯ | X |
| 39 | X | Δ | X |
| 40 | ◯ | ◯ | X |

As long as a colloidal silica having an average primary particle diameter ranging from 5 to 50 nm is incorporated in the slurry as shown in above Table 12, all of the results were found falling within the acceptable range as shown in the slurries Nos. 32-36. Especially as seen from the slurries of Nos. 33-35, when an average primary particle diameter of colloidal silica is confined within the range of 15 to 25 nm, it is possible to enhance the polishing rate of Cu film and to improve the dishing of Cu film.

When an average primary particle diameter of colloidal silica was too small (slurry of No. 31), the polishing rate of Cu film was unsatisfactory. On the other hand, when an average primary particle diameter of colloidal silica was too large (slurry of No. 37), it was impossible to suppress the generation of dishing of Cu film to an acceptable range.

Even if an average primary particle diameter of colloidal silica was confined within a predetermined range, it was impossible to suppress mainly the dishing of Cu film if an abrasive grain was constituted by materials (slurries of Nos. 38-40) other than colloidal silica. Especially, when alumina-based grain was employed as in the cases of slurries of Nos. 39 and 40, the generation of scratches tended to increase.

It was possible to confirm from the above results that a slurry comprising a predetermined quantity of basic amino acid, a water-insoluble complexing agent, a surfactant and colloidal silica having a predetermined primary particle diameter was capable of polishing Cu film at a polishing rate of 500 nm/min or more while suppressing the generation of the corrosion and dishing of Cu film.

### Embodiment 2

A structure as shown in FIG. 1 was obtained, wherein the width and intervals of the wiring trench “A” were both set to 65 nm. In this embodiment, in order to investigate the influence of the short by the residue of Cu, a barrier metal 15 was formed by a Ta film having a thickness of 15 nm. The Cu film 16 was removed by CMP to expose the surface of the barrier metal 15. As the slurry, the samples of Nos. 4, 8, 14, 2, 20, 31 and 39 were employed for performing the CMP under the same conditions as in the case of Embodiment 1.

The surface of the Cu film was observed using a defective-evaluating apparatus (KLA; Tenchol Co., Ltd.) and evaluated based on the existence or non-existence of Cu residue per cm² according to the following criterions.

◯: There was no Cu residue

×: Existence of Cu residue was confirmed

The results obtained from each of these slurries are summarized in the following Table 13.

Then, the kind of slurry was changed and CMP was repeated to remove the barrier metal 15 and, at the same time, the low dielectric constant insulating film 14 was shaved to remove 50 nm in thickness thereof (a second polishing).

In this second polishing, a top ring 23 holding a semiconductor substrate 22 was at first contacted with a polishing pad 21 at a polishing load of 200 gf/cm² while allowing a turntable 20 having a polishing pad 21 attached thereon to rotate at a speed of 100 rpm as shown in FIG. 3. The rotational speed of the top ring 23 was set to 102 rpm and a slurry 27 was fed from a slurry feed nozzle 25 to the polishing pad 21 at a flow rate of 200 cc/min.

The slurry was prepared by mixing each of the components formulated as follows with water. The contents of these components described below were all based on a total weight of the slurry.

Oxidizing agent: 0.3 wt % of hydrogen peroxide Water-insoluble complexing agent: 0.8 wt % of maleic acid

Surfactant: 0.05 wt % of acetylene diole-based nonion (HLB value 18)

Colloidal silica: 1.5 wt % of colloidal silica having a primary particle diameter of 30 nm (association degree: 1.5)

Potassium hydroxide was added as a pH adjustor to the slurry so as to adjust the pH thereof to 10.5, ultimately.

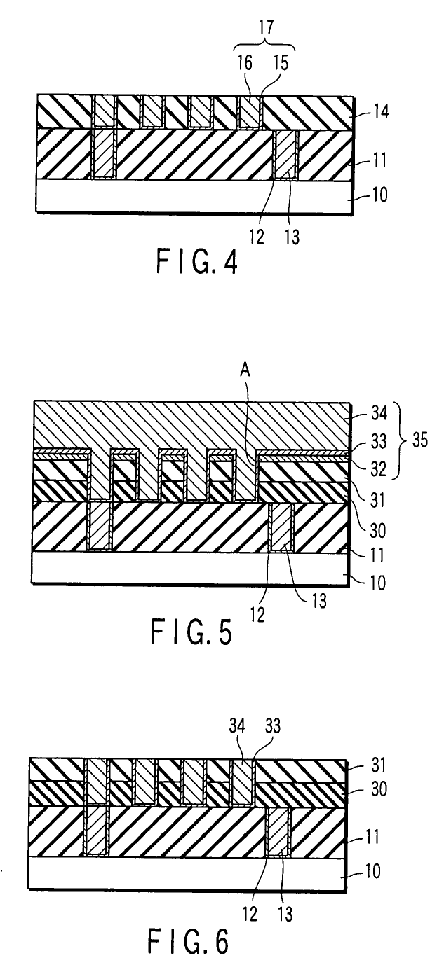

Using IC1000 (Nitta Harth Co., Ltd.) as the polishing pad 21, the polishing was performed for 55 seconds, thereby reducing the thickness of the low dielectric constant insulating film 14 by a thickness of 35 nm as shown in FIG. 4. Since the quantity of shaving of the low dielectric constant insulating film 14 was as small as 35 nm, it was difficult to completely remove the residue of Cu film that had been left behind on the barrier metal 15 even if in this second polishing. The residue of Cu film that could not be removed would become the generation of short of wiring after finishing the second polishing. Moreover, since the width of wiring is as thin as 65 nm, the phenomenon of open of wiring may be generated if the corrosion or dishing of Cu film is once generated.

Taking, as a sample, a wiring having a width of 65 nm, intervals of 65 nm and a length of 10 m, the magnitude of electric current thereof was measured to assess the Open and Short thereof. With respect to Open, if the electric current was 0.1 μA or more, it was determined as “◯” and if the electric current was less than 0.1 μA, it was determined as “×”. With respect to Short, if the electric current was 0.01 μA or less, it was determined as “◯” and if the electric current was higher than 0.01 μA, it was determined as “×”.

The results thus obtained are summarized in the following Table 13 together with the results of the residue of Cu.

TABLE 13

| Slurry | | | |
|---|---|---|---|
| No. | Residue | Open | Short |
| 4 | ◯ | ◯ | ◯ |
| 8 | ◯ | ◯ | ◯ |
| 14 | ◯ | ◯ | ◯ |
| 2 | X | ◯ | X |
| 20 | X | X | X |
| 31 | X | X | X |
| 39 | X | X | X |

As shown in above Table 13, when the polishing of Cu film was performed using slurries Nos. 4, 8 and 14, it was possible to prevent the generation of the residue of Cu. Incidentally, these slurries were those containing peroxosulfuric acid or a salt thereof, a predetermined quantity of basic amino acid, a water-insoluble complexing agent, a surfactant and colloidal silica having a predetermined primary particle diameter. Because of this, even if the second polishing was performed with the quantity of shaving of the insulating film being confined to as little as 35 nm, there was no likelihood of generating Short in the wiring to be obtained. Moreover, as described above, these slurries were found capable of suppressing the generation of the corrosion or dishing of Cu film. Accordingly, the wiring to be obtained as a result of the second polishing was prevented from being suffered from the cut-off of wiring or the thinning of wiring.

Therefore, when the polishing of the Cu film 16 was performed using the slurries of Nos. 4, 8 or 14, even if the second polishing was subsequently performed with a small quantity of shaving, it was possible to obtain a wiring which was capable of meeting the requirements on the Open and Short of wiring.

Whereas, when the polishing of the Cu film 16 was performed using the slurries of Nos. 2, 20, 31 or 39, the residue of Cu was left unremoved. In the case of the slurry of No. 2, basic amino acid was not included therein. In the case of the slurry of No. 20, peroxosulfuric acid or a salt thereof was not included therein. In the case of the slurry of No. 31, an average primary particle diameter of colloidal silica was too small. In the case of the slurry of No. 39, colloidal alumina was included therein. These slurries are all those of comparative example.

The residue of Cu that was left behind after the polishing of Cu film 16 could not be removed in the second polishing to give rise to the generation of Short of wiring and hence the results obtained therefrom were all determined as “×”. Further, since it was impossible to suppress the corrosion or dishing of Cu film, the result with regard to the Open of wiring was all determined as “×”.

### Embodiment 3

On the occasion of forming a trench to be filled with a Cu film by the RIE work in an insulating film having a relative dielectric constant of 3 or less, a mask material constituted by an insulating film made of SiN or SiO₂ is employed. In this case, the RIE selectivity ratio would be around 5. When a metal film is employed as a mask material, the RIE selectivity ratio can be enhanced to 10 or more. In this case, since the thin film of mask material can be further made thinner, it is advantageous in the fine working thereof. With respect to the polishing rate on the occasion of the CMP of Cu film, a metal film can be polished at a higher rate as compared with an insulating film such as SiN or SiO₂, the metal film can be easily removed. Because of this, it is possible, through the employment of a metal film as a mask material, to perform the polishing which makes it possible to reduce the polishing load and the concentration of abrasive grains and to minimize the mechanical stress. As a result, it is possible to reduce the erosion or damage to an insulating film having a relative dielectric constant of 3 or less.

In this embodiment, this structure is taken up as an example and explained with reference to FIGS. 5 and 6.

First of all, as shown in FIG. 5, an insulating film 11 formed of SiO₂ was deposited on a semiconductor substrate 10 having semiconductor elements (not shown) formed therein and then a plug 13 was formed in the insulating film 11 with a barrier metal 12 being interposed therebetween. The barrier metal 12 was formed by TiN, and the plug 13 was formed by W. Then, a first low dielectric constant insulating film 30 and a second low dielectric constant insulating film 31 were successively deposited all over the resultant surface to form a laminate insulating film. This first low dielectric constant insulating film 30 can be constituted by a low dielectric constant insulating material having a relative dielectric constant of less than 2.5. For example, this first low dielectric constant insulating film 30 can be formed using at least one selected from the group consisting of a film having a siloxane skeleton such as polysiloxane, hydrogen silsesquioxane, polymethyl siloxane, methylsilsesquioxane, etc.; a film comprising, as a major component, an organic resin such as polyarylene ether, polybenzooxazole, polybenzocyclobutene, etc.; and a porous film such as a porous silica film. In this embodiment, this first low dielectric constant insulating film 30 was formed by LKD (JSR Co., Ltd.).

The second low dielectric constant insulating film 31 to be deposited on the first low dielectric constant insulating film 30 acts as a capping insulating film and can be formed by an insulating material having a higher relative dielectric constant than that of the first low dielectric constant insulating film 30. For example, the second low dielectric constant insulating film 31 can be formed by an insulating film having a higher relative dielectric constant ranging from 2.5 to 3 and selected, for example, from the group consisting of SiC, SiCH, SiCN, SiOC and SiOCH. In this embodiment, the second low dielectric constant insulating film 31 was formed by SiOC.

Although it is possible to omit the first low dielectric constant insulating film 30 having a relative dielectric constant of less than 2.5, it is preferable to formulate the aforementioned laminate structure in order to sufficiently decrease the dielectric constant of the insulating film.

On this second low dielectric constant insulating film 31 was further deposited a TiN film having a thickness of 20 nm as a CMP sacrificial film 32. This CMP sacrificial film 32 may be formed by Ti, Ta, TaN, W, WN or Ru. In this case, since the polishing rate was relatively high, the CMP sacrificial film 32 was formed by TiN. A recess or a wiring trench “A” was formed so as to penetrate through the CMP sacrificial film 32, the second low dielectric constant insulating film 31 and the first low dielectric constant insulating film 30. Then, a Ti film having a thickness of 2 nm as a barrier metal 33 and a Cu film 34 having a thickness of 800 nm were deposited all over the surface by the ordinary method. In this manner, the CMP sacrificial film 32, the barrier metal 33 and the Cu film 34 were laminated to form a metal film 35.

Incidentally, the width and intervals of the wiring trench “A” were all set to 65 nm.

The Cu film 34, the barrier metal 33 and the CMP sacrificial film 32 all constituting the metal film 35 were removed, thus filling the wiring trench “A” with the metal film 35 and, at the same time, exposing the surface of the second low dielectric constant insulating film 31 as shown in FIG. 6.

In the CMP of the metal film 35, a top ring 23 holding a semiconductor substrate 22 was at first contacted with a polishing pad 21 at a polishing load of 200 gf/cm² while allowing a turntable 20 having a polishing pad 21 attached thereon to rotate at a speed of 100 rpm as shown in FIG. 3. The rotational speed of the top ring 23 was set to 105 rpm and a slurry 27 was fed from a slurry feed nozzle 25 to the polishing pad 21 at a flow rate of 200 cc/min.

Using various kinds of sample as shown in the following Table 14 as the slurry 27, the polishing of the metal film 35 was performed, thereby exposing the surface of the second low dielectric constant insulating film 31 as shown in FIG. 6. In the same manner as in the case of the aforementioned Embodiment 2, a wiring having a width of 65 nm, intervals of 65 nm and a length of 10 m was investigated with respect to the Open and the Short thereof. Further, the erosion of the second low dielectric constant insulating film 31 was investigated by AFM and assessed according to the following criterion. With respect to the erosion, when it was classified as being “◯” or “Δ”, it was determined as acceptable.

◯: less than 20 nm

Δ: 20 nm to less than 30 nm

×: 30 nm or more

Incidentally, when it was determined as being impossible to remove the CMP sacrificial film 32 and the barrier metal 33, it was defined as being “×”. The results thus obtained are summarized in the following Table 14.

TABLE 14

| Slurry | | | | SiOC |
|---|---|---|---|---|
| No. | Residue | Open | Short | erosion |
| 4 | ◯ | ◯ | ◯ | ◯ |
| 8 | ◯ | ◯ | ◯ | ◯ |
| 14 | ◯ | ◯ | ◯ | ◯ |
| 2 | X | ◯ | X | Δ |
| 20 | X | X | X | X |
| 31 | X | X | X | X |
| 39 | X | X | X | X |

As shown in above Table 14, when the polishing was performed using slurries Nos. 4, 8 and 14, it was possible to overcome the problems of Open and Short of wiring. These slurries were those containing peroxosulfuric acid or a salt thereof, a predetermined quantity of basic amino acid, a water-insoluble complexing agent, a surfactant and colloidal silica having a predetermined primary particle diameter.

When these slurries were employed, it was possible to prevent the corrosion of Cu film while making it possible to perform the polishing of Cu film at a high polishing rate and, at the same time, it was possible to increase the polishing rate of TiN employed as the CMP sacrificial film 32 up to 50 nm/min or more. Because of this, it was possible to easily remove the CMP sacrificial film 32 even if the content of colloidal silica employed as an abrasive grain was as small as 0.5 wt %. Moreover, it was possible to substantially prevent the generation of erosion of SiOC.

The slurry according to the embodiment of the present invention is also effective to various kinds of element such as Cu, Al, W, Ti, TiN, Ta, TaN, V, Mo, Ru, Zr, Mn, Ni, Fe, Ag, Mg, Mn and Si; to a laminate structure comprising any of these elements, or to a structure where a barrier metal does not substantially exist therein. The slurry according to the embodiment of the present invention is expected to exhibit almost the same effect on the occasion of forming a damascene wiring through the polishing of almost all kinds of metal.

According to one embodiment of the present invention, it is possible to provide a slurry for CMP which is capable of polishing a Cu film at a practical polishing rate without residue of Cu while suppressing the generation of dishing or corrosion of the Cu film. According to another embodiment of the present invention, it is possible to provide a method of polishing a Cu film at a practical polishing rate while suppressing the generation of defectives such as the dishing, corrosion or residue of the Cu film. According to a further embodiment of the present invention, it is possible to provide a method of manufacturing a semiconductor device having a high reliability wherein a damascene wiring can be formed through the polishing of a Cu film without generating the corrosion or dishing of the Cu film.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A slurry for CMP of Cu film comprising:
water;
peroxosulfuric acid or a salt thereof;
0.05 to 0.5 wt % of basic amino acid;
a complexing agent which forms a water-insoluble metal complex;
a surfactant; and
colloidal silica having a primary diameter ranging from 5 to 50 nm.

2. The slurry according to claim 1, wherein the salt of peroxosulfuric acid is selected from ammonium persulfate and potassium persulfate.

3. The slurry according to claim 1, wherein the peroxosulfuric acid or the salt is included at a content ranging from 0.05 to 5 wt % of the slurry.

4. The slurry according to claim 1, wherein the basic amino acid is selected from the group consisting of histidine, arginine, lysine and derivatives thereof.

5. The slurry according to claim 1, wherein the complexing agent is selected from the group consisting of quinaldinic acid, quinolinic acid, benzotriazole, benzoimidazole, 7-hydroxy-5-methyl-1,3,4-triazaindolizine, nicotinic acid and picolinic acid.

6. The slurry according to claim 1, wherein the complexing agent is included at a content ranging from 0.0005 to 2.0 wt % of the slurry.

7. The slurry according to claim 1, wherein the surfactant is selected from the group consisting of polyvinylpyrrolidone, acetylene glycol, ethylene oxide adducts thereof and acetylene alcohol.

8. The slurry according to claim 1, wherein the surfactant is included at a content ranging from 0.001 to 0.5 wt % of the slurry.

9. The slurry according to claim 1, wherein the colloidal silica is included at a content ranging from 0.05 to 10 wt % of the slurry.

10. The slurry according to claim 1, further comprising at least one selected from the group consisting of organic acids, basic salts and neutral amino acids.

11. The slurry according to claim 10, wherein the at least one selected from the group consisting of organic acids, basic salts and neutral amino acids is included at a content ranging from 0.01 to 0.5 wt % of the slurry.

12. A polishing method comprising:
contacting a semiconductor substrate having a Cu film with a polishing pad attached to a turntable; and
applying dropwise a slurry for CMP of Cu film to the polishing pad to polish the Cu film, the slurry comprising water; peroxosulfuric acid or a salt thereof; 0.05 to 0.5 wt % of basic amino acid; a complexing agent which forms a water-insoluble metal complex; a surfactant; and colloidal silica having a primary diameter ranging from 5 to 50 nm.

13. The method according to claim 12, wherein a polishing rate of the Cu film by the slurry is 500 nm/min or more.

14. A method for manufacturing a semiconductor device comprising:
forming an insulating film above a semiconductor substrate;
forming a recess in the insulating film;
forming a metal film including a barrier film and a Cu film successively on an inner surface of the recess and above the insulating film; and
removing the metal film deposited above the insulating film by CMP using a slurry for CMP of Cu film while leaving the metal film inside the recess, the slurry comprising water; peroxosulfuric acid or a salt thereof; 0.05 to 0.5 wt % of basic amino acid; a complexing agent which forms a water-insoluble metal complex; a surfactant; and colloidal silica having a primary diameter ranging from 5 to 50 nm.

15. The method according to claim 14, wherein a polishing rate of the Cu film by the slurry is 500 nm/min or more.

16. The method according to claim 14, wherein a barrier film is a Ti film and a polishing rate of the barrier film by the slurry is 5 nm/min or more.

17. A method for manufacturing a semiconductor device comprising:
forming an insulating film above a semiconductor substrate;
depositing a metal above the. insulating film to form a CMP sacrificial film;
forming a recess penetrating into the insulating film and the CMP sacrificial film;
forming a barrier film and a Cu film successively on an inner surface of the recess and on the CMP sacrificial film to obtain a metal film including the CMP sacrificial film, the barrier film and the Cu film; and
removing the metal film deposited above the insulating film by CMP using a slurry for CMP of Cu film to expose the insulating film, the slurry comprising water; peroxosulfuric acid or a salt thereof; 0.05 to 0.5 wt % of basic amino acid; a complexing agent which forms a water-insoluble metal complex; a surfactant; and colloidal silica having a primary diameter ranging from 5 to 50 nm.

18. The method according to claim 17, wherein a polishing rate of the Cu film by the slurry is 500 nm/min or more.

19. The method according to claim 17, wherein the CMP sacrificial film is formed of a material selected from the group consisting of TiN, Ti, Ta, TaN, W, WN and Ru.

20. The method according to claim 19, wherein a CMP sacrificial film is a TiN film and a polishing rate of the CMP sacrificial film by the slurry is 50 nm/min or more.
